(19) United States
(12) Patent Application Publication
(10) Pub. No.: US 2025/0169019 A1
(43) Pub. Date: May 22, 2025

(54) Server System Repositionable Peripheral Tray System

(71) Applicant: Dell Products L.P., Round Rock, TX (US)

(72) Inventors: Raymond DeWine Heistand, II, Round Rock, TX (US); Bruce Randall Hemingway, Austin, TX (US)

(73) Assignee: Dell Products L.P., Round Rock, TX (US)

(21) Appl. No.: 18/513,703

(22) Filed: Nov. 20, 2023

(51) Int. Cl. H05K 7/14

(52) U.S. Cl. CPC H05K 7/1489

(57) ABSTRACT

A repositionable tray system. The repositionable tray system includes a chassis; a repositionable peripheral tray, the repositionable tray includes a bottom wall; a left wall physically attached to the bottom wall, the left wall extending substantially perpendicularly from the bottom wall; a right wall physically attached to the bottom wall, the right wall extending substantially perpendicularly from the bottom wall; a one of a front wall and a rear wall physically attached to the bottom wall, the one of the front wall and the rear wall extending substantially perpendicularly from the bottom wall; and, a repositionable tray feature, the repositionable tray feature interacting with the chassis to enable the repositionable tray to be positioned in a plurality of tray orientations.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing a server system with a repositionable peripheral tray.

In one embodiment, the invention relates to a repositionable peripheral tray for use with an information handling system, comprising: a bottom wall; a left wall physically attached to the bottom wall, the left wall extending substantially perpendicularly from the bottom wall; a right wall physically attached to the bottom wall, the right wall extending substantially perpendicularly from the bottom wall; one of a front wall and a rear wall physically attached to the bottom wall, the one of the front wall and the rear wall extending substantially perpendicularly from the bottom wall; and, a repositionable tray feature, the repositionable tray feature interacting with a chassis of the information handling system to enable the repositionable tray to be positioned in a plurality of tray orientations.

In another embodiment, the invention relates to a chassis; and, a repositionable peripheral tray, the repositionable tray comprising a bottom wall; a left wall physically attached to the bottom wall, the left wall extending substantially perpendicularly from the bottom wall; a right wall physically attached to the bottom wall, the right wall extending substantially perpendicularly from the bottom wall; one of a front wall and a rear wall physically attached to the bottom wall, the one of the front wall and the rear wall extending substantially perpendicularly from the bottom wall; and, a repositionable tray feature, the repositionable tray feature interacting with a chassis of the information handling system to enable the repositionable tray to be positioned in a plurality of tray orientations.

In another embodiment, the invention relates to a system comprising: a chassis; a processor contained within the chassis; a data bus coupled to the processor; and, a repositionable peripheral tray system comprising a bottom wall; a left wall physically attached to the bottom wall, the left wall extending substantially perpendicularly from the bottom wall; a right wall physically attached to the bottom wall, the right wall extending substantially perpendicularly from the bottom wall; one of a front wall and a rear wall physically attached to the bottom wall, the one of the front wall and the rear wall extending substantially perpendicularly from the bottom wall; and, a repositionable tray feature, the repositionable tray feature interacting with a chassis of the information handling system to enable the repositionable tray to be positioned in a plurality of tray orientations.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIG. 4 shows a perspective view of a portion of server type information handling system with a chassis portion of a repositionable peripheral tray system.

FIGS. 5A and 5B, generally referred to as FIG. 5, respectively show a perspective view and a top view of a repositionable peripheral tray system.

FIGS. 6A and 6B, generally referred to as FIG. 6, show perspective views of a repositionable peripheral tray system in a plurality of positions.

FIGS. 7A and 7B, generally referred to as FIG. 7, show rear views of a repositionable peripheral tray system in a plurality of positions.

### DETAILED DESCRIPTION

Various aspects of the disclosure include an appreciation that it is known to provide information handling systems with devices which conform to specifications defined by an open compute project (OCP) foundation. Various aspects of the disclosure include an appreciation that an example of devices which conform to the OCP include OCP type network devices. Various aspects of the disclosure include an appreciation that an OCP type network device may be instantiated as an OCP network card. Various aspects of the present disclosure include an appreciation that an OCP network card is a standard form factor card that is commonly supported in servers. Various aspects of the present disclosure include an appreciation that known OCP card network cards mate with an OCP card receiving component circuit board via a straddle connector that resides on a receiving board of the OCP card receiving component. Various aspects of the present disclosure include an appreciation that the OCP card receiving component may be configured within a motherboard of an information handling system or may be a stand-alone component. When the OCP card receiving component is configured as a stand-alone component, the OCP card receiving component is referred to as a floating OCP component (i.e., FLOP component) or floating OCP receiving assembly (i.e., FLOP receiving assembly).

Various aspects of the disclosure include an appreciation that the open compute project (OCP) foundation has also defined a plurality of additional specifications some of which are within a datacenter modular hardware system (DC-MHS) family of specifications. Various aspects of the present disclosure include an appreciation that one such additional specification is the partial width, density optimized host processor module (HPM) form factor (referred to as an M-DNO form factor) base specification.

Various aspects of the disclosure include an appreciation that the HPM M-DNO specification defines a plurality of socket types. Various aspects of the disclosure include an appreciation that the plurality of socket types include a single socket type socket (referred to as a Type 2 socket) and a dual socket type socket (referred to as a Type 4 socket). Various aspects of the disclosure include an appreciation that it would be desirable to provide an information handling system chassis with an ability to be configured with mother boards (also referred to as planar boards) which can be used with the plurality of socket types.

Various aspects of the disclosure include an appreciation that a mother board which couples with a single socket type socket often includes two connectors for each socket. Various aspects of the disclosure include an appreciation that a mother board which couples with a dual socket type socket often includes three connectors for each socket. Various aspects of the disclosure include an appreciation that sockets which conform to the HPM M-DNO specification correspond to connectors available under the trade designation GenZ 4C+. These connectors allow for peripheral cards to be installed to an M-DNO type mother board via respective sockets.

Various aspects of the disclosure include an appreciation that it would be desirable to provide a single information handling system chassis to which a plurality of motherboards for respective socket types may be installed without requiring modification of the chassis. Various aspects of the disclosure include an appreciation that it would be desirable to provide a single information handling system chassis to which a single socket type socket motherboard and a dual socket type socket motherboard may be installed without requiring modification of the chassis.

A system and method are disclosed for providing a server type information handling system with a repositionable peripheral tray system which can accommodate a plurality of socket types without requiring modification of the information handling system chassis. In certain embodiments, the server type information handling system is provided with a repositionable peripheral tray system which can accommodate a single socket type socket motherboard and a dual socket type socket motherboard without requiring modification of the chassis.

In certain embodiments, the information handling system chassis includes three bays. In certain embodiments, the chassis is designed to allow for three peripheral cards to be installed through the rear wall bays (slots). The Peripheral Boards use guide rails within the chassis to ensure alignment with the Planar when installed. In certain embodiments, the sockets correspond to an M-DNO type socket.

In certain embodiments, the repositionable peripheral tray system incorporates a peripheral tray which is repositionable within the third rear wall bay of an information handling system chassis. This repositionable peripheral tray can readily be positioned to work with either a Type 2 Planar or Type 4 Planar using the same chassis. Repositioning is accomplished by keying slots and screws, which is also used for retention of the tray within the chassis. In certain embodiments, the repositionable peripheral tray interacts with keying and alignment features within the chassis utilized by the tray.

In certain embodiments, a Floating OCP Peripheral (a FLOP) Board can be used with Type 2 planar boards to allow the third peripheral card to be installed. The size of the Floating OCP Peripheral Board with the Type 2 Planar, the third 4C+ GenZ connector on the Floating OCP Peripheral Board is not inline with the third 4C+ GenZ connector on the Type 4 Planar (i.e., centers of connectors are offset). Various aspects of the disclosure include an appreciation that due to this offset, the bay for the third peripheral board should be larger to accommodate this offset. But this larger bay makes alignment rails impractical within the same chassis for use with the specific Type 2 or Type 4 planar boards.

Such a repositionable peripheral tray system advantageously provides an ability to mount a peripheral board within the same chassis using two form factor planar boards. Such a repositionable peripheral tray system advantageously provides an ability to mount peripheral connectors in different positions within the same chassis.

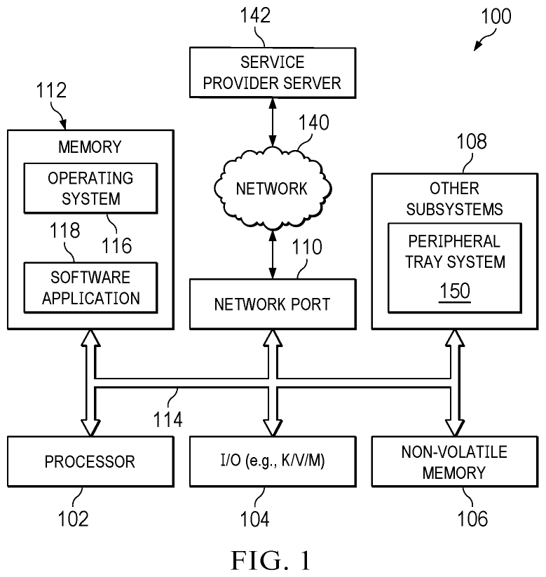

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, one or both the other subsystems 108 or the network port 110 include repositionable tray system 150. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the repositionable peripheral tray system 150 can accommodate a plurality of socket types without requiring modification of the information handling system chassis. In certain embodiments, the server type information handling system is provided with a repositionable peripheral tray system which can accommodate a single socket type socket motherboard and a dual socket type socket motherboard without requiring modification of the chassis. In certain embodiments, the repositionable peripheral tray system 150 includes one or more repositionable tray features. Each of the one or more the repositionable tray features interacting with a chassis of the information handling system to enable a repositionable tray to be positioned in a plurality of tray orientations. In certain embodiments, the plurality of tray orientations includes a first tray orientation and a second tray orientation.

In certain embodiments, the information handling system chassis includes three bays. In certain embodiments, the chassis is designed to allow for three peripheral cards to be installed through the rear wall bays (slots). The peripheral boards use guide rails within the chassis to ensure alignment with the planar board when installed. In certain embodiments, one or more of the sockets correspond to an M-DNO type socket.

In certain embodiments, the repositionable peripheral tray system 150 incorporates a peripheral tray which is repositionable within the rear wall bay (e.g., a third rear wall bay) of an information handling system chassis. This repositionable peripheral tray can readily be positioned to work with either a Type 2 Planar or Type 4 Planar using the same chassis. Repositioning is accomplished by keying slots and screws, which is also used for retention of the tray within the chassis. In certain embodiments, the repositionable peripheral tray interacts with keying and alignment features within the chassis utilized by the tray. In certain embodiments, the keying slots and screws and the keying and alignment features are each examples of respective repositionable tray features.

In certain embodiments, a Floating OCP Peripheral (a FLOP) Board can be used with Type 2 planar boards to allow the third peripheral card to be installed. The size of the Floating OCP Peripheral Board with the Type 2 Planar, the third 4C+ GenZ connector on the Floating OCP Peripheral Board is not inline with the third 4C+ GenZ connector on the Type 4 Planar (i.e., centers of connectors are offset). Various aspects of the disclosure include an appreciation that due to this offset, the bay for the third peripheral board should be larger to accommodate this offset. But this larger bay makes alignment rails impractical within the same chassis for use with the specific Type 2 or Type 4 planar boards.

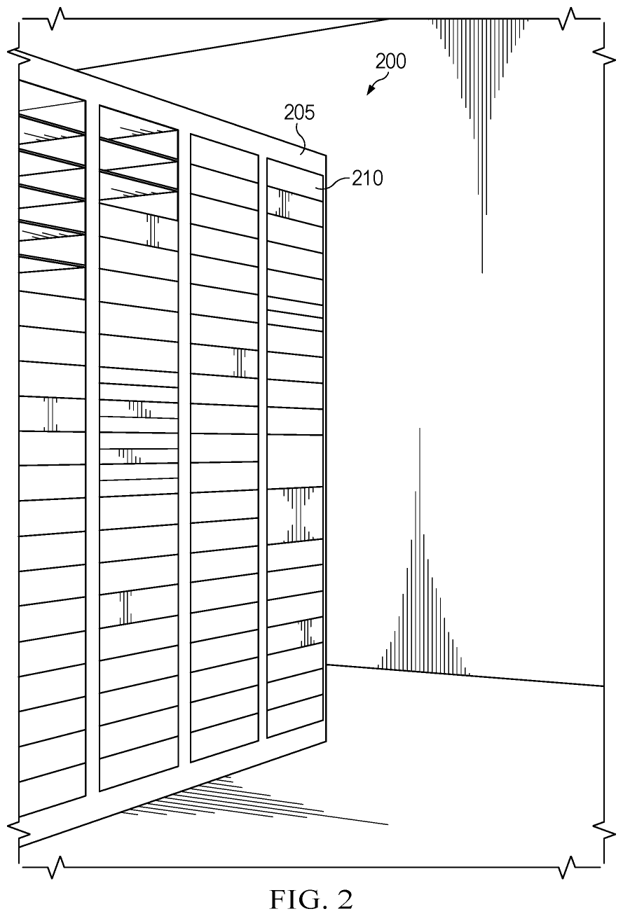

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100 as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuously with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit and a 4U rack unit. In general, a 1U rack unit is substantially (i.e., +/−20%) 1.75″ high, a 2U rack unit is substantially (i.e., +/−20%) 3.5″ high and a 4U rack height is substantially (i.e., +/−20%) 7.0″ high.

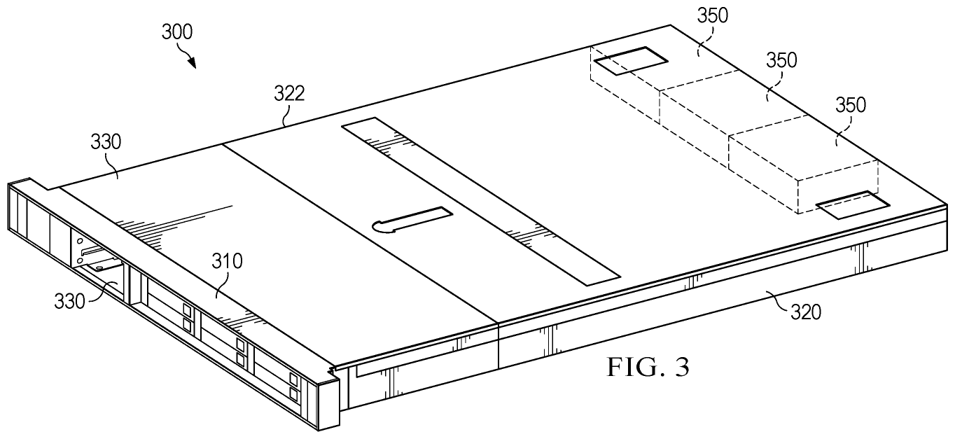

FIG. 3 shows a generalized perspective view of an example blade server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300. In certain embodiments, the blade type information handing system 300 includes a bay 350 via which components may be mounted to the blade type information handling system.

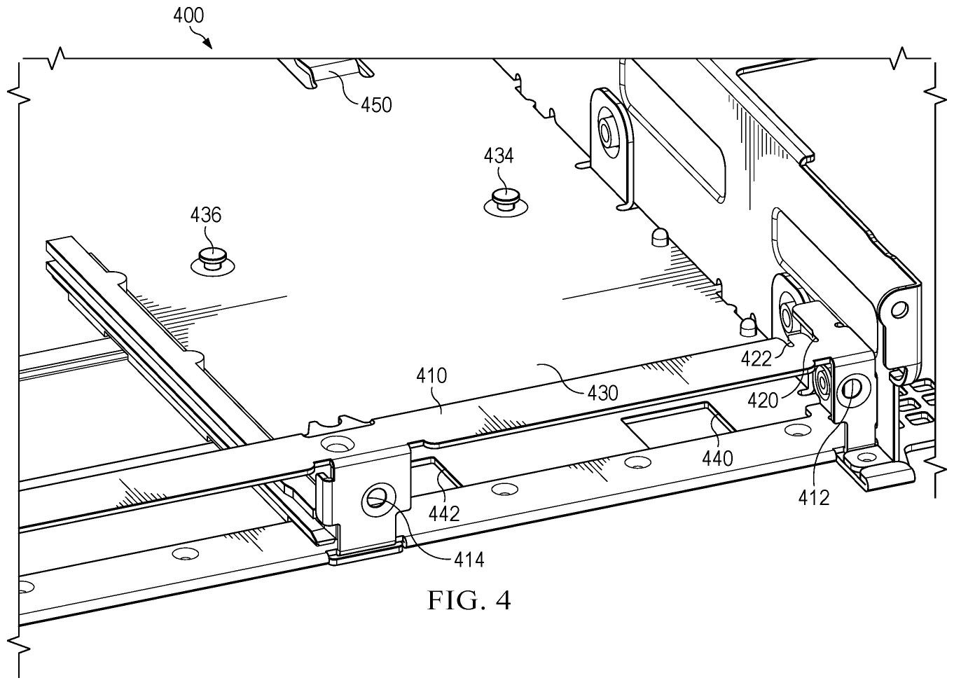

FIG. 4 shows a perspective view of a portion of server type information handling system with a chassis portion 400 of a repositionable peripheral tray system. More specifically, the chassis portion 400 of a repositionable peripheral tray system includes a rear wall portion 410. In certain embodiments, the rear wall portion 410 defines a right wall aperture 412, a left wall aperture 414, or a combination thereof. In certain embodiments, the right wall aperture 412, left wall aperture 414, or a combination thereof, are positioned to secure a tray within the chassis of the information handling system. In certain embodiments, a top wall of the rear wall portion 410 defines a right slot 420, a left slot 422, or a combination thereof. In certain embodiments, the right slot, left slot 422, or a combination thereof, interact with a tray alignment tab to align a front of a repositionable peripheral tray.

In certain embodiments, the chassis portion 400 of the repositionable peripheral tray system includes a tray base component 430. In certain embodiments, the tray base component 430 includes a right alignment and positioning component 434, a left alignment and positioning component 436, or a combination thereof. In certain embodiments, each alignment and positioning component 434, 436 includes a respective T-nut (also referred to as a T-Pin and sometimes as a key-hole slot pin). In certain embodiments, the tray base component 430 defines a right tab pass through aperture 440, a left tab pass through aperture 442, or a combination thereof. In certain embodiments, the right tab pass through aperture 440, left tab pass through aperture 442, or a combination thereof, allow with tray hold down tabs to pass through and interact underneath the rear wall portion 410 when a tray is mounted within the portion 400 of the information handling system chassis.

In certain embodiments, the base component 430 of the repositionable peripheral tray system includes a polarization recess 450. In certain embodiments, the polarization recess 450 interacts with a polarization tab of a peripheral tray when the peripheral tray is mounted within the portion 400 of the information handling system chassis.

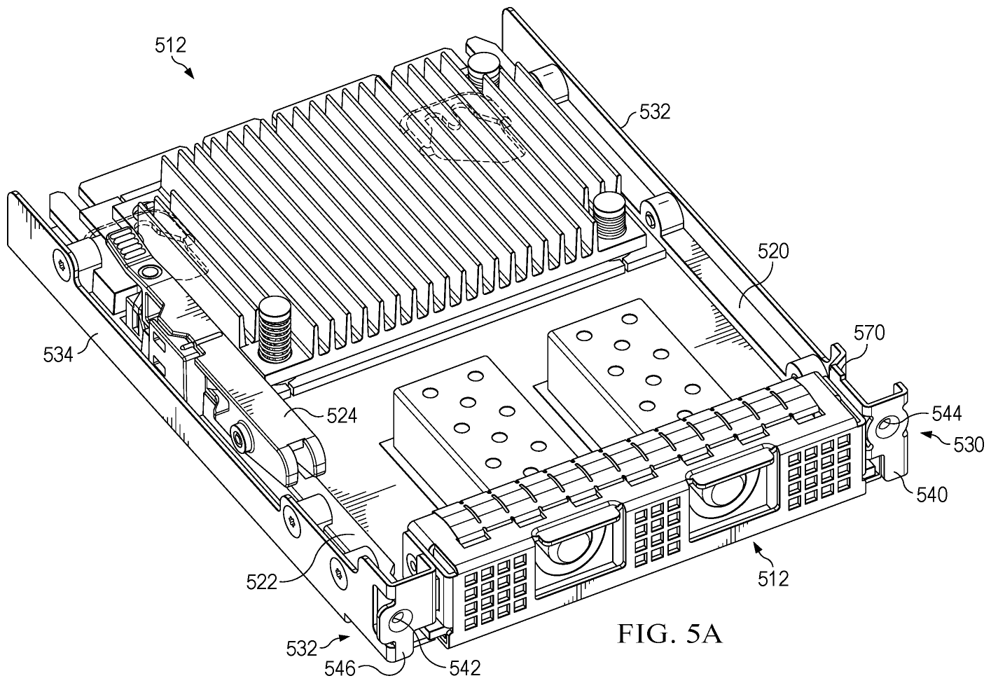

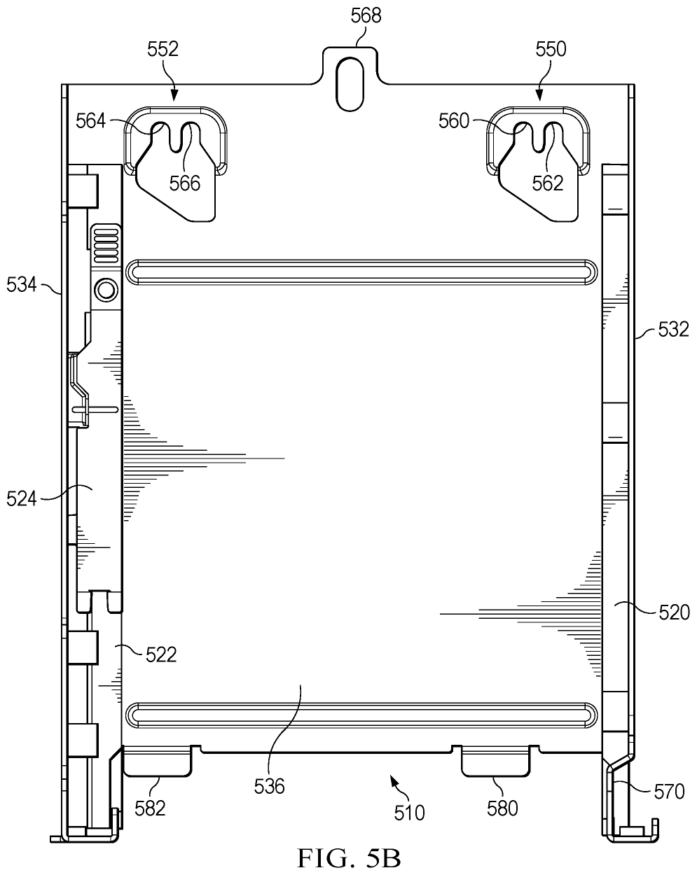

FIGS. 5A and 5B, generally referred to as FIG. 5, respectively show a perspective view and a top view of a portion 500 of a repositionable peripheral tray system. The perspective view of the portion of the repositionable tray system including a representation of a peripheral card installed on the repositionable tray. More specifically, the portion 500 includes a repositionable tray 510 and a peripheral card 512. In certain embodiments, the portion 500 of the repositionable peripheral tray includes a right peripheral card guide rail 520, a left peripheral card guide rail 522, or a combination thereof. In certain embodiments, the portion of the repositionable peripheral tray system includes a peripheral card latch 526.

In certain embodiments, the repositionable tray 510 includes a front wall 530, a right wall 532, a left wall 534, a bottom wall 536, or a combination thereof. In certain embodiments, the front wall 530 extends substantially perpendicularly (i.e., +/−20%) from the bottom wall 536. In certain embodiments, the right wall 532 extends substantially perpendicularly (i.e., +/−20%) from the bottom wall 536. In certain embodiments, the left wall 534 extends substantially perpendicularly (i.e., +/−20%) from the bottom wall 536.

In certain embodiments, the front wall 530 of the repositionable tray 510 includes a right front wall portion 540, a left front wall portion 542, or a combination thereof. In certain embodiments, the right front wall portion 540 defines a right front wall aperture 544. In certain embodiments, the left front wall portion 542 defines a left front wall aperture 546. In certain embodiments, the right front wall aperture 544 provides a mounting hole for a first type (e.g., a Type 2) of planar board implementation. In certain embodiments, the left front wall aperture 546 provides a mounting hole for a second type (e.g., a Type 4) of planar board implementation. In certain embodiments, the right front wall aperture 544, the left front wall aperture 546, or a combination thereof, are threaded to interact with a fastener when a repositionable peripheral tray is mounted within an information handling system chassis. In certain embodiments, the fastener is passed through one of a right wall aperture (e.g., right wall aperture 412) or a left wall aperture (e.g., left wall aperture 414) when a repositionable peripheral tray is mounted within an information handling system chassis.

In certain embodiments, the repositionable tray 510 includes a right keying portion 550, a left keying portion 552, or a combination thereof. In certain embodiments, the right keying portion 550 defines a plurality of key slots. In certain embodiments, each of the plurality of key slots of the right keying portion corresponds to a particular type of planar. In certain embodiments, the right keying portion 550 defines a first type key slot 560, a second type key slot 562, or a combination thereof. In certain embodiments, the left keying portion 552 defines a plurality of key slots. In certain embodiments, each of the plurality of key slots of the left keying portion 552 corresponds to a particular type of planar. In certain embodiments, the left keying portion 552 defines a first type key slot 564, a second type key slot 466, or a combination thereof. In certain embodiments, the key slots of the right keying portion 550 interact with an alignment and positioning component (e.g., right alignment and positioning component 434). In certain embodiments, the key slots of the left keying portion 533 interact with an alignment and positioning component (e.g., left alignment and positioning component 436).

In certain embodiments, the repositionable tray 510 of the repositionable peripheral tray system includes a polarization tab 568. In certain embodiments, the polarization tab 568 interacts with a polarization recess (e.g., polarization recess 450) when the peripheral tray is mounted within the information handling system chassis. In certain embodiments, a location of the polarization recess on a planar board is dependent on whether the planar board corresponds to a first type of planar board or a second type of planar board. Accordingly, the repositionable tray 510 can only be mounted in a position in the chassis corresponding to the type of planar board associated with the particular polarization recess.

In certain embodiments, one or both the right wall 532 or the left wall 534 of the repositionable tray 510 of the repositionable tray system includes a tray alignment tab 570. In certain embodiments, the tray alignment tab 570 interacts with one of a right slot (e.g., right slot 420) or a left slot (e.g., left slot 422) of a rear wall portion of the repositionable tray system depending on whether the repositionable tray is mounted within the information handling system chassis in a first orientation or a second orientation.

In certain embodiments, the bottom wall 536 includes a right hold down tab 580, a left hold down tab 582, or a combination thereof. In certain embodiments, the right hold down tab 580, the left hold down tab 582, or a combination thereof, pass through and interact with respective pass through apertures defined by the tray base component when a tray is mounted within an information handling system chassis.

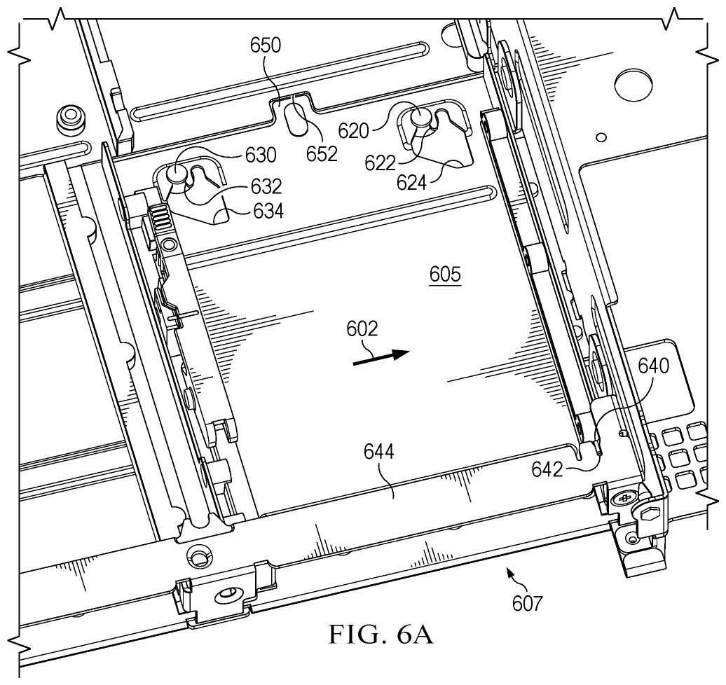

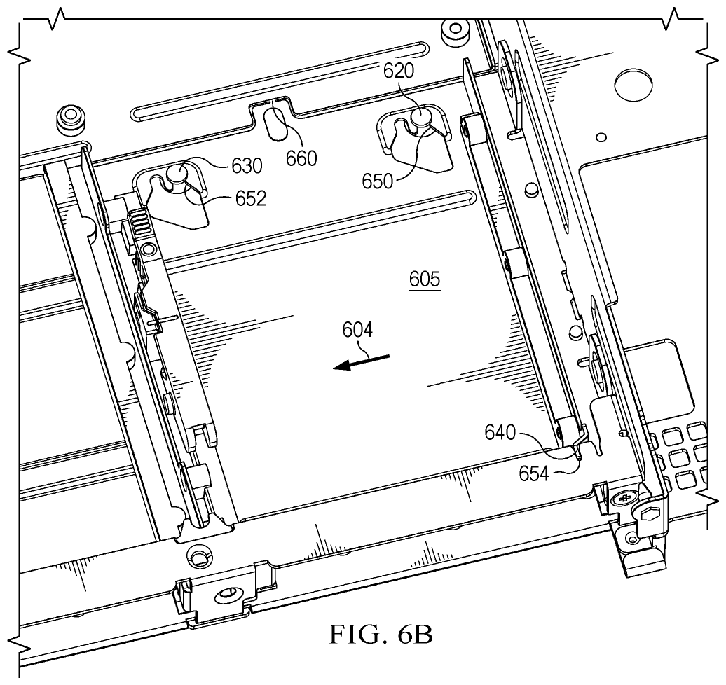

FIGS. 6A and 6B, generally referred to as FIG. 6, show perspective views of a repositionable peripheral tray system 600 in a plurality of positions. More specifically, FIG. 6A shows a perspective view of a repositionable peripheral tray system 600 in a mounting position for a first type of planar board implementation and FIG. 6B shows a perspective view of a repositionable peripheral tray system 600 in a mounting position for a second type of planar board implementation. In certain embodiments, the first type of planar board implementation corresponds to a Type 2 planar board implementation. In certain embodiments, the second type of planar board implementation corresponds to a Type 4 planar board implementation. In certain embodiments, the Type 2 planar board implementation corresponds to a single socket type (referred to as a Type 2 socket) planar board implementation defined by the HPM M-DNO specification. In certain embodiments, the Type 4 planar board implementation corresponds to a dual socket type (referred to as a Type 4 socket) planar board implementation defined by the HPM M-DNO specification.

In various embodiments, the peripheral tray 605 of the repositionable peripheral tray system 600 may be laterally shifted (as denoted by arrows 602, 604) within an information handling system chassis 607 between a first tray orientation and a second tray orientation. In various embodiments, the repositionable peripheral tray 605 of the repositionable peripheral tray system 600 may be laterally shifted within an information handling system chassis 607 depending on the type of planar board installed in the information handling system chassis. In certain embodiments, the lateral shifting is provided via one or more repositionable tray features.

In certain embodiments, when the repositionable peripheral tray 605 is in a first tray orientation, the right alignment and positioning component 620 fits within a first type key slot 622 of right keying portion 624 of the peripheral tray 605. In certain embodiments, when the repositionable peripheral tray 605 is in a first tray orientation, the left alignment and positioning component 630 fits within a first type key slot 632 of right keying portion 634 of the peripheral tray 605. In certain embodiments, the interaction of an alignment and positioning component 630, 636 with a respective keying portion 624, 634, provides a repositionable tray feature.

In certain embodiments, when the repositionable peripheral tray 605 is in a first tray orientation, the tray alignment tab 640 mates with a right slot 642 defined by a top wall 644 of a rear wall portion of a chassis. In certain embodiments, the polarization tab 650 interacts with a Type 2 polarization recess 652 defined by a Type 2 planar board when the peripheral tray is mounted within the information handling system chassis.

In certain embodiments, when the repositionable peripheral tray 605 is in a second tray orientation, the right alignment and positioning component 620 fits within a second type key slot 650 of right keying portion 624 of the peripheral tray 605. In certain embodiments, when the repositionable peripheral tray 605 is in a second tray orientation, the left alignment and positioning component 630 fits within a second type key slot 652 of right keying portion 634 of the peripheral tray 605. In certain embodiments, when the repositionable peripheral tray 605 is in a second tray orientation, the tray alignment tab 640 mates with a left slot 654 defined by a top wall 644 of a rear wall portion of a chassis. In certain embodiments, the interaction of a tray alignment tab 640 with the right slot 642 or the left slot 654 provides a repositionable tray feature. In certain embodiments, the polarization tab 650 interacts with a Type 2 polarization recess 660 defined by a Type 2 planar board when the peripheral tray is mounted within the information handling system chassis. In certain embodiments, the interaction of a polarization tab 650 with the polarization recess 652 or the polarization recess 660 provides a repositionable tray feature.

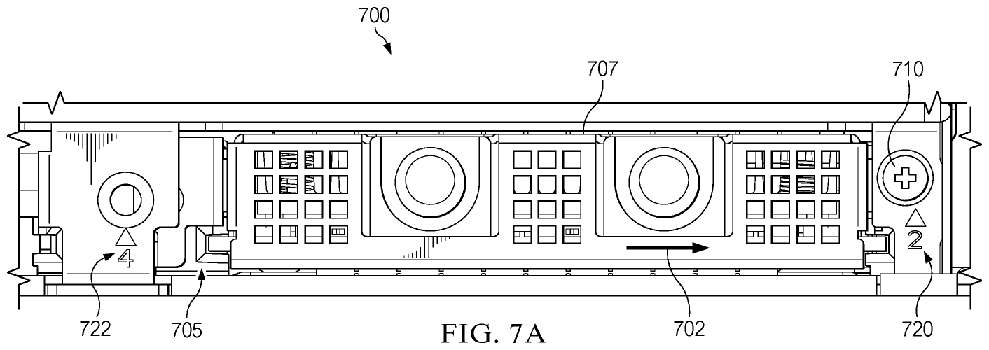

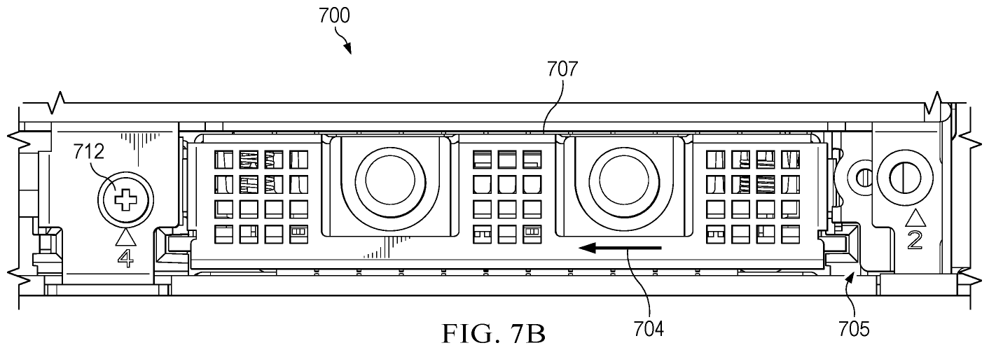

FIGS. 7A and 7B, generally referred to as FIG. 7, show rear views of a repositionable peripheral tray system in a plurality of positions. More specifically, FIG. 7A shows a rear view of a repositionable peripheral tray system 700 in a mounting position for a first type of planar board implementation and FIG. 7B shows a perspective view of a repositionable peripheral tray system 700 in a mounting position for a second type of planar board implementation. In certain embodiments, the first type of planar board implementation corresponds to a Type 2 planar board implementation. In certain embodiments, the second type of planar board implementation corresponds to a Type 4 planar board implementation. In certain embodiments, the Type 2 planar board implementation corresponds to a single socket type (referred to as a Type 2 socket) planar board implementation defined by the HPM M-DNO specification. In certain embodiments, the Type 4 planar board implementation corresponds to a dual socket type (referred to as a Type 4 socket) planar board implementation defined by the HPM M-DNO specification.

In various embodiments, the peripheral tray 705 and peripheral 707 of the repositionable peripheral tray system 700 may be laterally shifted (as denoted by arrows 702, 704) within an information handling system chassis between a first tray orientation and a second tray orientation. In various embodiments, the repositionable peripheral tray 705 of the repositionable peripheral tray system 700 may be laterally shifted within an information handling system chassis depending on the type of planar board installed in the information handling system chassis. In certain embodiments, the lateral shifting is provided via one or more repositionable tray features.

In certain embodiments, when the peripheral tray 705 and peripheral 707 are in a first tray orientation, a right front wall aperture defined by a right front wall portion of the chassis aligns with a right front wall aperture defined by the right front wall portion of the repositionable tray 705. In certain embodiments, when so aligned, a fastener 710 may pass through the right front wall aperture defined by the right front wall portion of the chassis and the right front wall aperture defined by the right front wall portion of the repositionable tray 705 to fasten the peripheral 707 to the chassis. In certain embodiments, the interaction of the right front wall aperture defined by the right front wall portion of the chassis with the right front wall aperture defined by the right front wall portion of the repositionable tray 705 provides a repositionable tray feature.

In certain embodiments, when the peripheral tray 705 and peripheral 707 are in a second tray orientation, a left front wall aperture defined by a left front wall portion of the chassis aligns with a left front wall aperture defined by the left front wall portion of the repositionable tray 705. In certain embodiments, when so aligned, a fastener 712 may pass through the left front wall aperture defined by the left front wall portion of the chassis and the left front wall aperture defined by the left front wall portion of the repositionable tray 705 to fasten the peripheral 707 to the chassis. In certain embodiments, the interaction of the left front wall aperture defined by a left front wall portion of the chassis with the left front wall aperture defined by the left front wall portion of the repositionable tray 705 provides a repositionable tray feature.

In certain embodiments, the front wall of the peripheral tray includes tray orientation indicia 720, 722. In certain embodiments, the tray orientation indicia 720, 722 provide an indication of which aperture to use to fasten a peripheral to the tray.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A repositionable peripheral tray for use with an information handling system, comprising:
a bottom wall;
a left wall physically attached to the bottom wall, the left wall extending substantially perpendicularly from the bottom wall;
a right wall physically attached to the bottom wall, the right wall extending substantially perpendicularly from the bottom wall;
one of a front wall and a rear wall physically attached to the bottom wall, the one of the front wall and the rear wall extending substantially perpendicularly from the bottom wall; and,
a repositionable tray feature, the repositionable tray feature interacting with a chassis of the information handling system to enable the repositionable tray to be positioned in a plurality of tray orientations.

2. The repositionable peripheral tray of claim 1, wherein:
the bottom wall defines a keying portion, the keying portion mating with an alignment and positioning component of the chassis of the information handling system, interaction of the alignment and positioning component with the keying portion providing the repositionable tray feature.

3. The repositionable peripheral tray of claim 1, wherein:
one of the right wall and the left wall of the repositionable peripheral tray include a tray alignment tab, the tray alignment tab mating with a slot defined by the information handling system chassis where interaction of the tray alignment tab and the slot providing the repositionable tray feature.

4. The repositionable peripheral tray of claim 1, wherein:
the bottom wall comprises a polarization tab, the polarization tab mating with a polarization recess defined by the information handling system chassis, where interaction of the polarization tab and the polarization recess providing the repositionable tray feature.

5. The repositionable peripheral tray of claim 1, wherein:
the one of the front wall and the rear wall of the repositionable tray defines a wall aperture, the wall aperture mating with a wall aperture defined by a wall portion of the chassis, interaction of the wall aperture of the repositionable tray with the wall aperture of the wall portion of the information handling system chassis providing the repositionable tray feature.

6. The repositionable peripheral tray of claim 1, wherein:
the plurality of tray orientations comprise a Type 2 Planar orientation and a Type 4 Planar orientation, the type 2 Planar orientation and the Type 4 Planar orientation corresponding to a partial width, density optimized host processor module (HPM) form factor (M-DNO form factor) base specification.

7. A repositionable peripheral tray system comprising:
a chassis; and,
a repositionable peripheral tray, the repositionable tray comprising
a bottom wall;
a left wall physically attached to the bottom wall, the left wall extending substantially perpendicularly from the bottom wall;
a right wall physically attached to the bottom wall, the right wall extending substantially perpendicularly from the bottom wall;
one of a front wall and a rear wall physically attached to the bottom wall, the one of the front wall and the rear wall extending substantially perpendicularly from the bottom wall; and,
a repositionable tray feature, the repositionable tray feature interacting with the chassis to enable the repositionable tray to be positioned in a plurality of tray orientations.

8. The repositionable peripheral tray system of claim 7, wherein:
the bottom wall defines a keying portion, the keying portion mating with an alignment and positioning component of the chassis of the information handling system, interaction of the alignment and positioning component with the keying portion providing the repositionable tray feature.

9. The repositionable peripheral tray system of claim 7, wherein:
one of the right wall and the left wall of the repositionable peripheral tray include a tray alignment tab, the tray alignment tab mating with a slot defined by the information handling system chassis where interaction of the tray alignment tab and the slot providing the repositionable tray feature.

10. The repositionable peripheral tray system of claim 7, wherein:
the bottom wall comprises a polarization tab, the polarization tab mating with a polarization recess defined by the information handling system chassis, where interaction of the polarization tab and the polarization recess providing the repositionable tray feature.

11. The repositionable peripheral tray system of claim 7, wherein:
the one of the front wall and the rear wall of the repositionable tray defines a wall aperture, the wall aperture mating with a wall aperture defined by a wall portion of the chassis, interaction of the wall aperture of the repositionable tray with the wall aperture of the wall portion of the information handling system chassis providing the repositionable tray feature.

12. The repositionable peripheral tray system of claim 11, wherein:
the plurality of tray orientations comprise a Type 2 Planar orientation and a Type 4 Planar orientation, the type 2 Planar orientation and the Type 4 Planar orientation corresponding to a partial width, density optimized host processor module (HPM) form factor (M-DNO form factor) base specification.

13. A system comprising:
a chassis;
a processor contained within the chassis;
a data bus coupled to the processor; and,
a repositionable peripheral tray system comprising
a bottom wall;
a left wall physically attached to the bottom wall, the left wall extending substantially perpendicularly from the bottom wall;
a right wall physically attached to the bottom wall, the right wall extending substantially perpendicularly from the bottom wall;
one of a front wall and a rear wall physically attached to the bottom wall, the one of the front wall and the rear wall extending substantially perpendicularly from the bottom wall; and,
a repositionable tray feature, the repositionable tray feature interacting with the chassis to enable the repositionable tray to be positioned in a plurality of tray orientations.

14. The system of claim 13, wherein:
the bottom wall defines a keying portion, the keying portion mating with an alignment and positioning component of the chassis of the information handling system, interaction of the alignment and positioning component with the keying portion providing the repositionable tray feature.

15. The system of claim 13, wherein:
one of the right wall and the left wall of the repositionable peripheral tray include a tray alignment tab, the tray alignment tab mating with a slot defined by the information handling system chassis where interaction of the tray alignment tab and the slot providing the repositionable tray feature.

16. The system of claim 13, wherein:
the bottom wall comprises a polarization tab, the polarization tab mating with a polarization recess defined by the information handling system chassis, where interaction of the polarization tab and the polarization recess providing the repositionable tray feature.

17. The system of claim 13, wherein:
the one of the front wall and the rear wall of the repositionable tray defines a wall aperture, the wall aperture mating with a wall aperture defined by a wall portion of the chassis, interaction of the wall aperture of the repositionable tray with the wall aperture of the wall portion of the information handling system chassis providing the repositionable tray feature.

18. The system of claim 17, wherein:
the plurality of tray orientations comprise a Type 2 Planar orientation and a Type 4 Planar orientation, the type 2 Planar orientation and the Type 4 Planar orientation corresponding to a partial width, density optimized host processor module (HPM) form factor (M-DNO form factor) base specification.
